(19) United States
(12) Patent Application Publication
(10) Pub. No.: US 2008/0063948 A1
(43) Pub. Date: Mar. 13, 2008

(54) METHOD FOR ACHIEVING COMPLIANT SUB-RESOLUTION ASSIST FEATURES

(76) Inventor: Sean O'Brien, Dallas, TX (US)

Correspondence Address: TEXAS INSTRUMENTS INCORPORATED, P O BOX 655474, M/S 3999, DALLAS, TX, 75265, US

(21) Appl. No.: 11/531,048

(22) Filed: Sep. 12, 2006

(51) Int. Cl. G03C 5/00; G06F 17/50; G03F 1/00

(52) U.S. Cl. 430/5; 716/19; 716/21; 430/311; 430/313

(57) ABSTRACT

The present application is directed to a process of forming a photomask pattern comprising one or more sub-resolution assist features (SRAF). The process comprises generating a first set of SRAF patterns. Each of the SRAF patterns in the first set having a first assigned mask position. After the first set of SRAF patterns are generated, determining if the SRAF patterns of the first set comply with a preselected set of rules, wherein one or more of the SRAF patterns are found to be illegal because they do not comply with at least one of the preselected rules. One or more of the illegal SRAF patterns are reassigned to second mask positions that are different from the first mask positions, the second mask positions allowing the illegal SRAF patterns to comply with the at least one preselected rule to form corrected SRAF patterns. The present application also discloses systems for generating a sub-resolution assist feature pattern for a photomask, as well as SRAF modules embodied on a computer readable medium comprising instructions operable to carry out the processes of the present application.

### DESCRIPTION OF THE DISCLOSURE

1. Field of the Disclosure

The present application relates generally to the field of photolithography, and more specifically to a method for preparing a mask pattern that can be used for making a photomask.

2. Background of the Disclosure

Conventional optical projection lithography has been the standard silicon patterning technology for the past 20 years. It is an economical process due to its inherently high throughput, thereby providing a desirable low cost per part or die produced. A considerable infrastructure (including steppers, photomasks, resists, metrology, etc.) has been built up around this technology.

In this process, a mask, or “reticle”, includes a mask pattern for defining device features to be patterned, often formed of, for example, opaque chrome on a transparent glass substrate. A stepper projects light through the mask and images the mask pattern, often with a 4× to 5× reduction factor, onto a photo-resist film formed on a wafer.

As the critical dimensions of integrated circuits continue to decrease, there is a need to pattern smaller and smaller features. Modern photolithographic systems often employ light in the imaging process which has a larger wavelength than the critical dimensions of the device features being formed on the integrated circuits. When critical dimensions are printed at less than or equal to the wavelength of light being used, the wave properties of the light become a dominant property of the lithography. In general, these wave properties are seen as being a limiting factor in lithography.

Due to the limitations of photolithographic systems, the patterns formed in the photoresist generally do not coincide exactly with the mask patterns formed on the reticle. Conventional masks often compensate for this phenomenon by forming a mask with features that differ somewhat from the feature desired to be patterned in the photoresist material.

For example, isolated features, which are located in a region of the mask having relatively few mask features, will almost always print at a feature size significantly different from the same mask feature surrounded by a relatively large number of features. This phenomena, known as iso-dense bias, is caused by the variation in light intensity from the differing feature densities of the different mask regions. To correct for iso-dense bias, sub-resolution assist features (SRAF), also known as scattering bars, are added to the mask. The SRAF are designed to increase the light intensity of an isolated feature region so that it is more similar to denser feature regions, and therefore allow the isolated feature to print at the same feature size as the feature in the dense feature regions.

Some reticles, known as dark field reticles, are mainly chrome with device features opened up where the light is transparent. Other reticles, known as bright field reticles, are mainly transparent, with the features being defined by chrome. In dark field reticles, the transparent device feature patterns are said to have a negative tone, while in bright field reticles, the chrome device feature patterns are said to have a positive tone.

For any given reticle, the SRAF can be both positive and negative tone. For example, on a bright field reticle, some SRAF can be formed of chrome, while other SRAF may be be formed of transparent glass (where, for example, a piece of chrome defines a main feature and the SRAF are formed by removing pieces of the chrome feature).

The SRAF is a sub-resolution feature and, therefore, is not meant to print. This is in contrast to the main features of the mask, which are designed to print so as to produce a photoresist pattern. The size and position of the SRAF are carefully adjusted so that it does not print over the needed process window. Thus, SRAF are designed to be large enough to create a denser mask pattern, but not so large as to print. If SRAFs are not sized and positioned properly to reduce iso-dense bias, the pattern formed in the photo-sensitive material will not correctly correspond to the photomask pattern.

The SRAFs are generally sized and positioned using computer software. The software employs a set of SRAF rules during generation of the SRAF to specify such things as the number of SRAF that should be formed between main features, as well as the mask tone (positive or negative), shape length and width of the SRAF. The software also employs other rules, such as mask and/or process rules, to achieve the desired mask quality and help insure that the mask pattern meets the desired specifications. Mask rules come from the reticle vendor and are associated with the manufacturing specifications and quality of the reticle. Process rules, on the other hand, are designed to reduce the risk of printing failures. Examples of printing failures include printing SRAF, and SRAF interfering with optical proximity correction. In general, the SRAF are sized and positioned according to the SRAF rules, and then checked for compliance with the mask and/or process rules.

It has been found that SRAF, while being positioned according to the SRAF rules, may still violate other mask rules. Such SRAF are deemed “illegal.” In the past, the policy has been that illegal SRAF generally are not allowed on the photomask, and are therefore deleted. However, it has been determined that simply deleting illegal SRAF may cause certain problems, such as failure to reduce iso-dense bias and/or the inability of the optical proximity correction process to arrive at a mask pattern solution with acceptable process margin. Accordingly, improved techniques for dealing with illegal SRAF are desired.

### SUMMARY OF THE DISCLOSURE

In accordance with the disclosure, one embodiment of the present application is directed to a process of forming a photomask pattern comprising one or more sub-resolution assist features (SRAF). The process comprises generating a first set of SRAF patterns. Each of the SRAF patterns in the first set having a first assigned mask position. After the first set of SRAF patterns are generated, determining if the SRAF patterns of the first set comply with a preselected set of rules, wherein one or more of the SRAF patterns are found to be illegal because they do not comply with at least one of the preselected rules. One or more of the illegal SRAF patterns are reassigned to second mask positions that are different from the first mask positions, the second mask positions allowing the illegal SRAF patterns to comply with the at least one preselected rule to form corrected SRAF patterns.

Another embodiment of the present application is directed to a system for correcting a sub-resolution assist feature (SRAF) pattern for a photomask. The system comprises a database operable to store data describing one or more integrated circuit features having target dimensions. An SRAF module is coupled to the database. The SRAF module is embodied on a computer readable medium and comprises a set of instructions operable to reassign one or more illegal SRAF patterns having first assigned mask positions to second mask positions that are different from the first mask positions.

Another embodiment of the present application is directed to an SRAF module embodied on a computer readable medium. The SRAF module comprises a set of instructions operable to reassign one or more illegal SRAF patterns having first assigned mask positions to second mask positions that are different from the first mask positions.

Additional embodiments and advantages of the disclosure will be set forth in part in the description which follows, and can be learned by practice of the disclosure. The embodiments and advantages of the disclosure will be realized and attained by means of the elements and combinations particularly pointed out in the appended claims.

It is to be understood that both the foregoing general description and the following detailed description are exemplary and explanatory only and are not restrictive of the disclosure, as claimed.

The accompanying drawings, which are incorporated in and constitute a part of this specification, illustrate several embodiments of the disclosure and, together with the description, serve to explain the principles of the disclosure.

### BRIEF DESCRIPTION OF THE DRAWINGS

FIG. 1 illustrates a flow chart of a process of forming a photomask pattern comprising one or more sub-resolution assist features (SRAF), according to one embodiment of the present application.

FIG. 2A illustrates a first and second SRAF pattern, according to an embodiment of the present application.

FIGS. 2B and 2C illustrate the SRAF patterns of FIG. 2A that have been reassigned to new positions, according to embodiments of the present application.

FIG. 3A illustrates a first and second SRAF pattern, according to an embodiment of the present application.

FIGS. 3B and 3C illustrate the SRAF patterns of FIG. 3A that have been reassigned to new positions, according to embodiments of the present application.

FIG. 4 illustrates a system 70 for forming an SRAF pattern, according to an embodiment of the present application.

### DESCRIPTION OF THE EMBODIMENTS

Reference will now be made in detail to various exemplary embodiments of the present application, examples of which are illustrated in the accompanying drawings. Wherever possible, the same reference numbers will be used throughout the drawings to refer to the same or like parts.

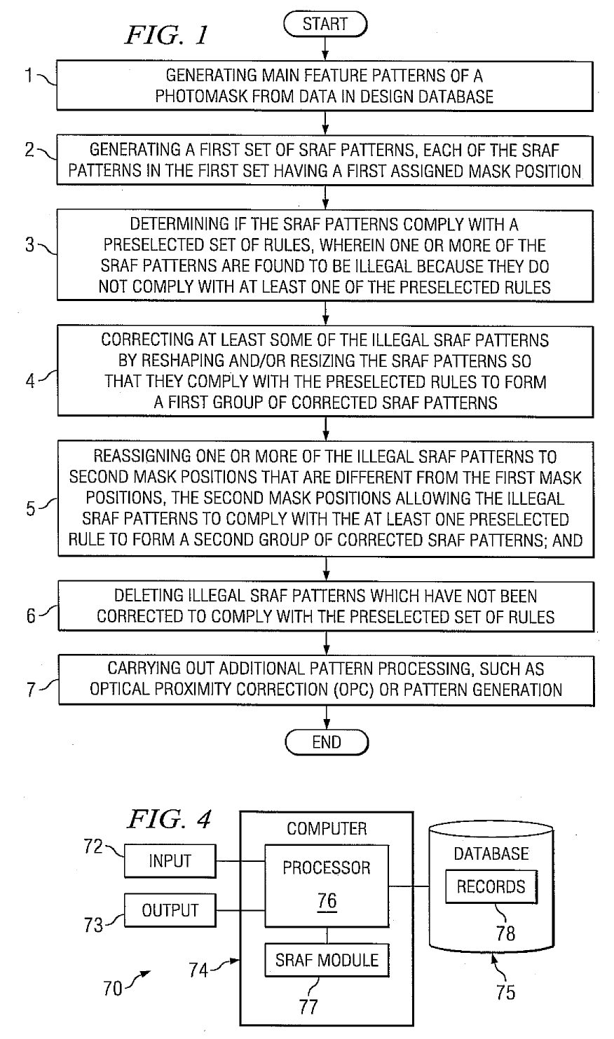

FIG. 1 illustrates a flow chart of a process of forming a photomask pattern comprising one or more sub-resolution assist features (SRAF), according to one embodiment of the present application. The photomask may be used for patterning any suitable device features, such as, for example, integrated circuit devices.

Referring to FIG. 1, the main features of the mask can be generated based on photomask design data stored in a design database at 1, which can, for example, describe target features of an integrated circuit design. The main photomask features generally include polygon shaped patterns designed so as to print photoresist patterns that will achieve the target device features described in the design data base, once the wafer processing is carried out. Employing the design data, any suitable software program may be used to generate the main features of the mask. Methods and software for forming the main photomask features from the design data base are well known in the art. One example of a suitable mask generation software program is—HERCULES™, which is available from Synopsis Inc.

At 2, the process illustrated in the embodiment of FIG. 1 includes generating a first set of SRAF patterns. Each of the SRAF patterns can be assigned a mask position by the software according to the SRAF rules. The SRAF patterns can be generated and assigned positioned using any suitable SRAF software program. One example of a suitable SRAF placement program is PROTEUS™, which is available from Synopsis Inc.

At 3, the process of the FIG. 1 embodiment further includes determining if the generated SRAF patterns comply with a preselected set of rules. The preselected rules can be different from the SRAF rules, and may include, for example, process rules and mask rules, which are collectively referred to herein as “compliance rules”. Suitable examples of process rules include limits on the SRAF shape, restrictions on total length or width of the SRAF, and restrictions on the length or width of a portion of the SRAF, such as the length of an arm where the SRAF has an L-shape. Suitable examples of mask rules include restrictions on the minimum distance between two adjacent chrome patterns, or restrictions on the minimum width of a chrome pattern. In some embodiments, the software used to generate the SRAF patterns can also be employed to determine if the SRAF patterns comply with the preselected compliance rules. SRAF patterns that do not comply with the compliance rules are considered illegal. In general, illegal SRAF patterns are not desirable, and may be either corrected or deleted. However, in some embodiments illegal SRAF may be included on the photomask depending on the photomask making protocol employed.

At 4 of the embodiment of FIG. 1, if it is determined that one or more of the SRAF patterns generated in the process described at 2 are illegal, attempts may be made to correct the illegal SRAF patterns so that they comply with both the SRAF rules and compliance rules. Such corrections may involve editing or reprogramming the software algorithm and/or data to reshape and/or resize the SRAF patterns. For example, if it is determined that an SRAF pattern is so large that it will print, the size of the SRAF may be decreased. In yet other embodiments, the shape of the SRAF may be altered so that the SRAF satisfies the compliance rules.

Since it is generally the case that a certain percentage of SRAF patterns cannot be resized or reshaped during the process at 4 so as to satisfy all compliance rules, the SRAF patterns corrected in the process at 4 may be checked against the compliance rules to determine which, if any of them, still fail to comply with the compliance rules. If it is determined that some of the illegal SRAF are not corrected during the process at 4 to comply with all the mask making rules, it may be possible to reposition at least some of the remaining illegal SRAFS in a manner which allows them to comply with the mask making rules, as set forth at 5 of FIG. 1.

Thus, SRAF found to violate the compliance rules after the process at 4 can be reassigned to a second mask position that is different from the originally assigned SRAF position. In this manner, another group of illegal SRAF patterns can be corrected, in addition to the SRAF patterns corrected as described with reference to 4.

The second SRAF position may allow the SRAF pattern to comply with the preselected compliance rules, even though it may not necessarily comply with all SRAF rules. As discussed above, each SRAF is assigned a first position on the mask according to the SRAF rules, and by reassigning the SRAF to a second position, the SRAF rules may consequently be violated. However, it has been found that it is often the case that it is better to include the SRAF on the photomask, even though it fails to comply with the original SRAF position dictated by the SRAF generating software, rather than delete the SRAF altogether.

After the SRAF patterns are repositioned by the process at 5, additional checks may be carried out to determine if the repositioned SRAF patterns comply with all of the preselected compliance rules. In some embodiments, any repositioned SRAF patterns that are found to violate compliance rules at this point in the process may be deleted. In other embodiments, the processes at 4 and/or 5 may be repeated in an attempt to correct the remaining illegal SRAF patterns so that they comply with the compliance rules. For example, the SRAF pattern may be reassigned to a third position which is different than the second assigned position. In another embodiment, the SRAF may be left in the second position, but resized and/or reshaped, as described in the process at 4, so as to comply with the compliance rules. The processes at 4 and/or 5 may be repeated multiple times in this manner until it is determined that all the SRAF patterns either comply with the preselected compliance rules or have been deleted.

Additional processing may be carried out once all the SRAF patterns have been determined to either comply with the compliance rules or have been deleted. Examples of such additional processing can include, for example, optical proximity correction (OPC) to correct for optical proximity effects, as indicated at 6. Any suitable technique for correcting for optical proximity effects may be employed. Examples of suitable optical phase correction techniques are disclosed in U.S. Pat. No. 6,764,795, issued on Jul. 20, 2004 to Aton et al., the disclosure of which is herein incorporated by reference in its entirety.

After OPC, pattern generation can be carried, which is a process carried out by a computer program that prepares the mask data to go to the mask writer. Suitable software for carrying out pattern generation is well known in the art. One example of a suitable software program known in the art for pattern generation is HERCULES, which is available from SYNOPSYS.

The photomask pattern data prepared using the process of the embodiment of FIG. 1 can then used to write the photomask. Often the mask data is sent to an independent mask writer, where the photomasks are made. Any suitable technique for writing the photomask can be used. Suitable techniques for writing photomasks are well known in the art.

The embodiments of the present application are not intended to be limited to the processes illustrated in FIG. 1. For example, the processes illustrated in each of the blocks of FIG. 1 may be performed in a different order than is shown, or may be eliminated from the process. Other additional processes not shown in the flow diagram of FIG. 1 may also be employed. For example, one or more of the processes at 3, 4, 5 and 6 may be repeated any desired number of times after OPC at 7, in order to determine if any illegal SRAF exist after OPC, and correct or delete them if they do exist.

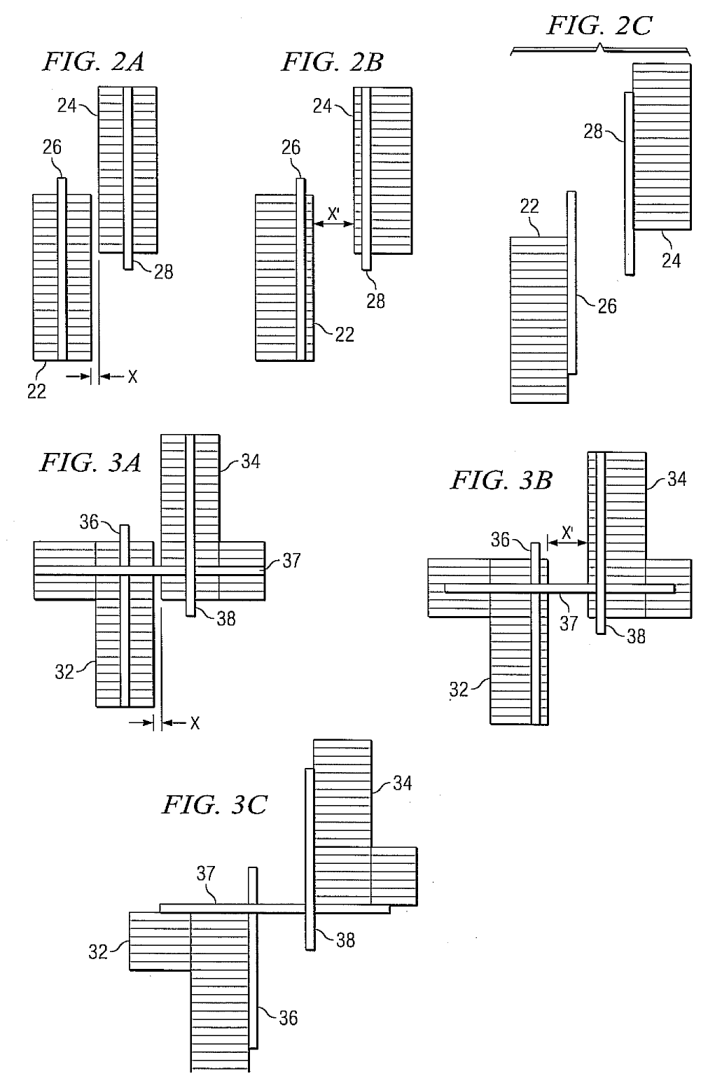

FIGS. 2A to 2C illustrate examples of reassigning SRAF patterns to a second mask position that is different from the originally assigned mask position, as described above with reference 5 of the FIG. 1 embodiment. FIG. 2A shows a first SRAF pattern 22 and a second SRAF pattern 24. SRAF pattern 22 is originally assigned to a first mask position 26, while SRAF 24 is originally assigned to a first mask position 28 as described above with reference to 2 of FIG. 1. In this embodiment, the SRAF patterns 22 and 24 may be determined to be illegal because a distance x is less than a minimum spacing distance, as set by a preselected compliance rule.

In order to comply with the minimum spacing rule, SRAF patterns 22 and 24 are each assigned to a second mask position. The second mask positions may be determined by any appropriate method that will satisfy the minimum spacing rule.

In one example, the distance x between SRAF 22 and SRAF 24 resulting from the originally assigned mask positions may be 4 nm, while the minimum spacing rule may require x to be, for example, 40 nm. One or both of the SRAF may be moved a distance that will provide at least the distance needed to meet the minimum spacing rule. For example, each SRAF in the above example may be moved a distance of about 18 nm in opposite directions, to provide the distance x′, as illustrated in FIG. 2B, where x′ satisfies the minimum spacing rule. In addition, it may be possible to input minimum and maximum distances that each SRAF may be moved into the software program, and then allow the software to choose the second positions of each SRAF within the desired minimum and maximum distances. For the above example, it may be possible to input a minimum distance of, for example, 12 nm that each SRAF may be moved, and a maximum distance of 25 nm, so long as the total distance between the SRAF satisfies the minimum spacing of 40 nm that is required by the rule for this example. It is to be understood that the specific distances used herein are for illustrative purposes only, and are not intended to limit the claims in any way.

The SRAF patterns can be moved in any direction in the plane of the mask to satisfy the minimum distance requirement. For example, in an x, y Cartesian coordinate system, the SRAF patterns may be moved along an x-axis, a y-axis, or, as illustrated in FIG. 2C, along both the x and y axis. In some embodiments, minimum and maximum distances in both the x and y axes directions may be input into the software program.

The SRAF are not limited to any particular shape. For example, the SRAF patterns may be rectangles, as in the embodiment of FIG. 2, or they may be any other suitable polygon shape, such as the shapes illustrated in the embodiment of FIG. 3A to 3C. Still other shapes may be contemplated by one of ordinary skill in the art.

As shown in the embodiment of FIGS. 3A to 3C, the SRAF patterns 32 and 34 may be moved from the original positions defined by first mask positions 36, 37, and 38, to a second mask position, similarly as described above with respect to FIG. 2. The SRAF patterns 32 and 34 may be moved along an x-axis, a y-axis, or, as illustrated in FIG. 3C, along both the x and y axes Minimum and maximum distances in both the x and y axis directions may be input into the software program, as desired, in order to satisfy the compliance rules.

FIG. 4 illustrates a system 70 for forming an SRAF pattern. System 70 includes an input device 72 and an output device 73 coupled to a computer 74, which is in turn coupled to a database 75. Input device 72 may include, for example, a keyboard, a mouse, or any other device suitable for transmitting data to computer 74. Output device 73 may include, for example, a display, a printer, or any other device suitable for outputting data received from computer 74.

Computer 74 may include a personal computer, workstation, network computer, wireless computer, or one or more microprocessors within these or other devices, or any other suitable processing device. Computer 74 may include a processor 76, and an SRAF module 77. Computer 74 may also include other modules, as desired.

The above SRAF module 77 can exist as software that includes program instructions in source code, object code, executable code or other formats; program instructions implemented in firmware; or hardware description language (HDL) files. Any of the above can be embodied on a computer readable medium, which include storage devices and signals, in compressed or uncompressed form. Exemplary computer readable storage devices include conventional computer system RAM (random access memory), ROM (read-only memory), EPROM (erasable, programmable ROM), EEPROM (electrically erasable, programmable ROM), and magnetic or optical disks or tapes.

Processor 76 controls the flow of data between input device 72, output device 73, database 751 and SRAF module 77. SRAF module 77 may receive data from database 75, which may include, for example, design data for target features of integrated circuit devices to be patterned, and data describing main feature patterns generated from a main feature generation module (not shown) for printing the target features from the design data. Using such data, the SRAF module 77 can generate SRAF patterns, as described above. SRAF module 77 can then determine if the generated SRAF patterns comply with a preselected set of compliance rules, and identify any illegal SRAF patterns that fail to comply. If any SRAF are identified as illegal the SRAF module 77 can then generate corrected SRAF patterns, as described above. The modules may include instructions operable to prompt the user for input during the above processes, as desired.

In other embodiments, the processes for generating SRAF, determining if the SRAF comply with the preselected compliance rules, and correcting SRAF, may be accomplished by separate modules, which may be stored on separate databases and/or employed by separate processors. For example, the process of generating SRAF may be carried out on a first processor; and the process of determining if the SRAF comply with the rules and then correcting illegal SRAF may be carried out on a second processor.

Database 75 may include any suitable system for storing data. Database 75 may store records 78 that include data associated with the integrated circuit device features to be patterned. Examples of such data include design data for the device features, photomask pattern data, and any other data, such as data regarding SRAF rules and/or compliance rules that may be used to determine if the generated SRAF patterns comply.

Embodiments of the present application are directed to an integrated circuit device and method of forming the integrated circuit device by employing a photomask having a photomask pattern prepared by the processes of the present application. The integrated circuit devices can be prepared by, for example, applying a photoresist to a wafer using techniques well known in the art. The photoresist is then exposed to radiation through a photomask having a photomask pattern prepared by any of the processes of the present application, as described herein. The photoresist can be developed using techniques well known in the art to form a photoresist pattern on the wafer. Processes such as etching or ion implantation can then be carried out using the photoresist pattern to, for example, selectively etch or selectively ion implant portions of the device by techniques well known in the art in order to form features of the integrated circuit device.

In some embodiments, forming the integrated circuit device using a photomask having photomask patterns generated using the processes of the present application can result in improved patterning of the integrated circuit. For example, where SRAF patterns are corrected by reassigning illegal SRAF patterns to second mask positions, as described in 5 of the embodiment of FIG. 1, it may result in formation of integrated circuit features with dimensions that are closer to the desired target dimensions than if the illegal SRAF were simply deleted.

For the purposes of this specification and appended claims, unless otherwise indicated, all numbers expressing quantities, percentages or proportions, and other numerical values used in the specification and claims, are to be understood as being modified in all instances by the term “about.” Accordingly, unless indicated to the contrary, the numerical parameters set forth in the following specification and attached claims are approximations that can vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques.

It is noted that, as used in this specification and the appended claims, the singular forms “a,” “an,” and “the,” include plural referents unless expressly and unequivocally limited to one referent. Thus, for example, reference to “an acid” includes two or more different acids. As used herein, the term “include” and its grammatical variants are intended to be non-limiting, such that recitation of items in a list is not to the exclusion of other like items that can be substituted or added to the listed items.

While particular embodiments have been described, alternatives, modifications, variations, improvements, and substantial equivalents that are or can be presently unforeseen can arise to applicants or others skilled in the art. Accordingly, the appended claims as filed and as they can be amended are intended to embrace all such alternatives, modifications variations, improvements, and substantial equivalents.

What is claimed is:

1. A process of forming a photomask pattern comprising one or more sub-resolution assist features (SRAF), the process comprising:
generating a first set of SRAF patterns, each of the SRAF patterns in the first set having a first assigned mask position;
determining if the SRAF patterns of the first set comply with a preselected set of rules, wherein one or more of the SRAF patterns are found to be illegal because they do not comply with at least one of the preselected rules; and
reassigning one or more of the illegal SRAF patterns to second mask positions that are different from the first mask positions, the second mask positions allowing the illegal SRAF patterns to comply with the at least one preselected rule to form corrected SRAF patterns.

2. The process of claim 1, further comprising correcting at least one of the illegal SRAF patterns by reshaping and/or resizing the SRAF patterns so that they comply with the preselected rules.

3. The process of claim 1, wherein the first set of SRAF patterns comprise a first SRAF pattern spaced a distance x from a second SRAF pattern, wherein x is smaller than a minimum distance required by the at least one preselected rule.

4. The process of claim 3, wherein during the reassigning process, the first SRAF pattern and the second SRAF patterns are both assigned second mask positions that increase x, thereby complying with the desired minimum distance.

5. The process of claim 1, further comprising a process of determining if the reassigned SRAF patterns in the second mask positions comply with the preselected set of rules.

6. The process of claim 5, further comprising deleting any SRAF patterns in the second mask positions that do not comply with the preselected set of rules.

7. The process of claim 5, wherein if any of the reassigned SRAF patterns do not comply, further comprising assigning one or more reassigned SRAF patterns that do not comply with the preselected set of rules to third mask positions that are different from the second mask positions.

8. The process of claim 7, further comprising repeating the process of reassigning SRAF patterns that do not comply with the preselected set of rules to different mask positions until it is either determined that all the SRAF patterns comply with the preselected set of rules, or it is determined that the non-compliant SRAF patterns should be deleted.

9. The process of claim 1, wherein if any of the reassigned SRAF patterns do not comply, further comprising correcting one or more of the reassigned SRAF patterns in the second mask positions that do not comply with the preselected set of rules by at least one technique chosen from reshaping and resizing the SRAF.

10. The process of claim 1, further comprising carrying out an optical proximity correction process, wherein the reassigning process is carried out prior to the optical proximity correction process.

11. The process of claim 1, further comprising carrying out an optical proximity correction process, wherein the reassigning process is carried out after the optical proximity correction process.

12. A method of forming an integrated circuit device, the method comprising:
applying a photoresist to a wafer;
exposing the photoresist to radiation through a photomask having a photomask pattern prepared by the method of claim 1;
developing the photoresist to form a photoresist pattern on the wafer; and
processing the wafer using the photoresist pattern.

13. An integrated circuit device formed by the process of claim 12.

14. A system for correcting a sub-resolution assist feature (SRAF) pattern for a photomask, the system comprising:
a database operable to store data describing one or more integrated circuit features having target dimensions; and
an SRAF module coupled to the database, wherein the SRAF module is embodied on a computer readable medium and comprises a set of instructions operable to reassign one or more illegal SRAF patterns having first assigned mask positions to second mask positions that are different from the first mask positions.

15. The system of claim 14, wherein the SRAF module further comprises instructions operable to identify the one or more illegal SRAF patterns by determining whether the SRAF patterns comply with a preselected set of rules.

16. The system of claim 15, wherein the SRAF module further comprises instructions operable to correct illegal SRAF patterns by at least one technique chosen from reshaping and resizing the SRAF patterns, so that the illegal SRAF patterns comply with the preselected rules.

17. The system of claim 15, wherein the SRAF module further comprises instructions operable to determine if the reassigned SRAF patterns in the second mask positions comply with the preselected set of rules.

18. The system of claim 17, wherein the SRAF module further comprises instructions operable to delete any SRAF patterns in the second mask positions that do not comply with the preselected set of rules.

19. An SRAF module embodied on a computer readable medium, the SRAF module comprising a set of instructions operable to reassign one or more illegal SRAF patterns having first assigned mask positions to second mask positions that are different from the first mask positions.

20. The system of claim 19, wherein the SRAF module further comprises instructions operable to identify the one or more illegal SRAF patterns by determining whether the SRAF patterns comply with a preselected set of rules.

21. The SRAF module of claim 20, further comprising instructions operable to correct illegal SRAF patterns by at least one technique chosen from reshaping and resizing the SRAF patterns, so that the illegal SRAF patterns comply with the preselected rules.

22. The SRAF module of claim 20, further comprising instructions operable to determine if the reassigned SRAF patterns in the second mask positions comply with the preselected set of rules.

23. The SRAF module of claim 22, further comprising instructions operable to delete any SRAF patterns in the second mask positions that do not comply with the preselected set of rules.
